(19) United States
(12) Patent Application Publication
(10) Pub. No.: US 2026/0331899 A1
(43) Pub. Date: Oct. 22, 2026

(54) GROUND FAULT INTERRUPTER WITH REMOTE TESTING AND RESETTING PROVISION

(71) Applicant: Cyient Ltd., Hyderabad (IN)

(72) Inventors: Akshatha Pai, Bangalore (IN); Sanjiv C. Komati, Bangalore (IN); Vinaya Krishna Bandaru, Mandapeta (IN); Sunil Shantilal Patel, Rockford, IL (US)

(73) Assignee: Cyient Ltd., Hyderabad (IN)

(21) Appl. No.: 19/180,323

(22) Filed: Apr. 16, 2025

(51) Int. Cl. H02H 3/16; G01R 31/327; H02H 1/00; H02H 3/06

(52) U.S. Cl. CPC H02H 3/16; G01R 31/3277; H02H 1/0007; H02H 1/0061; H02H 3/066

(57) ABSTRACT

Proposed Ground Fault Interrupter (GFI) (100) includes a current transformer (106) for sensing current flowing across a line supplying electrical power to a load. The GFI (100) further includes a controller (102) for sensing ground fault current in a secondary winding (114) of the current transformer (106), determining that the ground fault current exceeds a predefined current value for a predefined time period, and sending, a first instruction to an Electronic Circuit Board (ECB) (130) to deactivate a switch (132) meant for transferring the electrical power from the line (108) to the load, for protecting the load (110) from the ground fault current. The GFI (100) further includes the first CAN transceiver (120) configured to receive a second instruction over a CAN bus (140) for resetting position of the switch (132), after the ground fault current is handled.

### FIELD OF INVENTION

The present invention generally relates to electrical protection devices. More specifically, the present invention is related to circuit interrupters.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also correspond to implementations of the claimed technology.

In electrical power distribution applications, there is possibility of occurrence of short circuits in electrical loads,. One of the main reasons of these short circuit is ground fault, specifically in fuel tank load applications. Ground fault occurs when one or more of the supply phases comes into contact of ground due to insulation breakdown or wrong wiring connections. Ground fault can cause damage to equipment as well as result in loss of life.

Ground fault effects can be arrested using Ground Fault Interrupters (GFIs). A GFI is used to protect a load from short circuit by disconnecting the load from power supply during the event of ground fault. However, the testing of the GFIs is required to be done manually with the power applied, which is not recommended due to personnel safety. Further, during an adverse event, such as upon detection of ground fault current, when GFIs tripped,, resetting of the GFIs is required to be done manually by physically accessing the GFIs installed in the airplane.

Further, conventional GFIs operate on a particular value or limited range of ground fault current. Due to such reason, separate GFIs operable for different current values are required to be manufactured, and this results into a burden on stock keeping of the GFIs.

Therefore, there is a need of a GFI that can address the above-mentioned shortcomings.

### OBJECTS OF THE INVENTION

A general objective of the invention is to develop a system for detection of latent failures of Ground Fault Interrupt (GFI) circuits in an electrical distribution application remotely.

Another objective of the invention is to develop a programmable unit for setting a GFI trip level and GFI fault current detection time with a provision of remote resetting for tripped GFI.

Yet another objective of the invention is to develop a common GFI circuit for different load ratings.

### SUMMARY OF THE INVENTION

This summary is provided to introduce aspects related to a Ground Fault Interrupter (GFI), and the aspects are further described below in the detailed description. This summary is not intended to identify essential features of the claimed subject matter nor is it intended for use in determining or limiting the scope of the claimed subject matter.

In one embodiment, the GFI comprises a current transformer for sensing ground fault current flowing through a power line supplying electrical power to a load. The GFI further comprises a controller configured to receive details of the ground fault current from the current transformer. The GFI is further configured to determine that the ground fault current exceeds a predefined current value for a predefined time period. The GFI is further configured to send a first instruction over a discrete electrical signal to an Electronic Circuit Board (ECB) to deactivate a switch meant for transferring the electrical power from the line to the load, for protecting the load from the ground fault current. The GFI further comprises the first Controller Area Network (CAN) transceiver configured to receive a second instruction over a CAN bus for resetting position of the switch, after the ground fault current is handled.

In one aspect, the GFI further comprises a GFI driver for generating a test signal in a test winding of the current transformer as a part of Built-in Test (BITE), during remote testing of the GFI. The test signal is generated based on a third instruction received from the controller and results into generation of the ground fault current in the secondary winding.

In one aspect, the controller sends the third instruction to the driver circuit based on a user command provided using a Graphical User Interface (GUI) of a remote device connected with the CAN bus.

In one aspect, the GFI comprises a non-volatile memory for storing a lock out flag when the ground fault current exceeds a predefined current value and a predefined time period has passed or BITE test fails, during remote testing of the GFI.

In one aspect, the predefined current value and the predefined time period are configurable.

In one aspect, the switch is a semiconductor switch selected from a group consisting of Metal-oxide-semiconductor Field-effect Transistor (MOSFET), thyristor, and Insulated-Gate Bipolar Transistor (IGBT).

In one aspect, the GFI comprises a signal conditioning circuit for processing the ground fault current and providing a value of the ground fault current to the controller.

In one aspect, the GFI eliminates dormant failure of a GFI sensing function.

### BRIEF DESCRIPTION OF THE DRAWINGS

The accompanying drawings constitute a part of the description and are used to provide a further understanding of the present invention.

FIG. 1 illustrates a schematic block diagram of a Ground Fault Interrupter (GFI), in accordance with an embodiment of the present invention.

FIG. 2 illustrates a flowchart of a method of RCI command flow in the GFI, in accordance with an embodiment of the present invention.

FIG. 3 illustrates a flowchart of a method of ground fault detection by the GFI, in accordance with an embodiment of the present invention.

FIG. 4 illustrates a flowchart of a method of resetting the GFI after ground fault detection, in accordance with an embodiment of the present invention.

FIG. 5 illustrates a flowchart of a method of performing predictive maintenance and diagnostics of a GFI using remote function, in accordance with an embodiment of the present invention.

### DETAILED DESCRIPTION OF THE INVENTION

The detailed description set forth below in connection with the appended drawings is intended as a description of various embodiments of the present invention and is not intended to represent the only embodiments in which the present invention may be practiced. Each embodiment described in this disclosure is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details.

The present invention pertains to a system for interruption of electrical faults in an electrical distribution circuit. In an embodiment, a Ground Fault Interrupt (GFI) circuit may be used for detection of ground fault currents in electrical units of electrical distribution network. The GFI circuit comprises a self-test feature as a part of Built-In Test Equipment (BITE) for testing operation of the GFI. The GFI circuit further comprising a programmable unit for setting a threshold current levels and detection time of such current levels in the GFI circuit. A CAN bus command may be used for initiating the test remotely and resetting after clearing the fault as required during maintenance. A current sense transformer in the GFI circuit may be used for detecting and measuring ground fault current. More details pertaining to the abovementioned embodiment is given below.

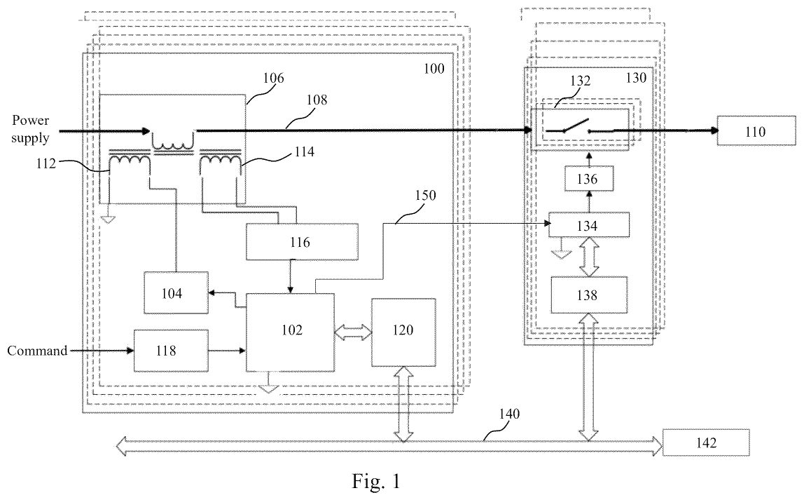

FIG. 1 illustrates a schematic block diagram of a Ground Fault Interrupter (GFI) 100, in accordance with an embodiment of the present invention. The GFI 100 includes a controller 102 configured to manage operation of other elements of the GFI 100 for protecting an electrical load from ground fault current. One such element is a GFI driver 104. The GFI driver 104 is connected with the controller 102 and a current transformer 106. The current transformer 106 is configured to sense ground fault current flowing through a power line 108 supplying electrical power to a load 110. The current transformer 106 includes a test winding 112 and a secondary winding 114. The secondary winding 114 is connected with a signal conditioning circuit 116. The signal conditioning circuit 116 is also connected with the controller 102 and configured to provide a current value sensed by the current transformer 106 to the controller 102 after suitable processing. The GFI 100 also includes a Relay Control Interface (RCI) circuit 118 and a first Controller Area Network (CAN) transceiver 120. The RCI circuit 118 when activated, supplies the electrical power to the load 110. The first CAN transceiver 120 allows communication of the GFI 100 with external elements or units. A command for testing operation of the GFI 100 is generated automatically each time the RCI 118 is turned ON, in addition to on-demand during maintenance.

The ECB 130 includes a switch 132 meant for transferring the electrical power from the line 108 to the load 110. The switch 132 is a semiconductor switch selected from a group consisting of Metal-oxide-semiconductor Field-effect Transistor (MOSFET), thyristor, and Insulated-Gate Bipolar Transistor (IGBT). The ECB 130 also includes an ECB microcontroller 134, an ECB driver 136, and a second CAN transceiver 138. The ECB microcontroller 134 sends command to the ECB driver 136 for altering operational state of the switch 132 based on a first instruction received via a discrete electrical signal 150 from the controller 102 during an adverse event, such as upon detection of ground fault current. In such condition, the switch 132 is deactivated for protecting the load 110 from the ground fault current. Successively, a Graphical User Interface (GUI) of a remote device 142 sends a second instruction to GFI 100 over the CAN bus 140 for resetting position of the switch 132 via discrete electrical signal 150, after the ground fault current is handled.

Before operating the GFI 100 during a ground fault event, it is also possible to remotely test functionality of the GFI 100. To remotely test functionality of the GFI 100, a user may provide a command (user command) from the GUI of the remote device 142 connected with the CAN bus 140. Communication of instructions and commands over the CAN bus 140 provides the benefits including low-cost, built-in error detection, robustness, speed, and flexibility. The RCI activation command from system interface may be received by the RCI circuit 118 and interfaced to the controller 102. In response to the activation command, the controller 102 sends a third instruction to the driver circuit 104 for generating a test signal in the test winding 112 of the current transformer 106. The test signal in the test winding 112 results into generation of ground fault current in the secondary winding 114. The ground fault current is picked and processed by the signal conditioning circuit 116 and a value of the ground fault current is provided to the controller 102. The controller 102 determines whether the ground fault current exceeds a predefined current value for a predefined time period, and sends the first instruction to the ECB 130 for deactivating the switch 132 when the condition is identified to be true. The predefined current value and the predefined time period are configurable by a user and may be stored in a memory (not illustrated) of the GFI 100. In one implementation, the memory may be non-volatile and may store a lock out flag when the ground fault current exceeds predefined current value and the predefined time or BITE test fails, during remote testing of the GFI 100. Further, the controller 102 may send a fault indication to the GUI of the remote device 142 upon identifying GFI fault. The lock out flag representing a data field/entry indicates improper functioning of remote testing of the GFI 100, and need of hardware repair/replacement such as of the switch 132.

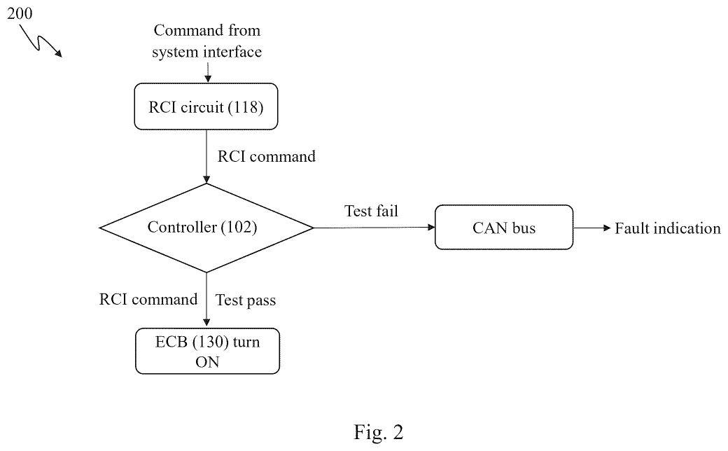

FIG. 2 illustrates a flowchart 200 of a method of RCI command flow in the GFI 100, in accordance with an embodiment of the present invention. A command received from a system interface may be provided to the RCI circuit 118 for turning ON a GFI protected load, such as the load 110. The RCI circuit 118 may then send an RCI command to the controller 102. In response, the controller 102 implements and tests operation of a ground fault detection function. The controller 102 allows an associated Electronic Circuit Breaker (ECB) 130 to turn ON when it is determined that the ground fault detection function is operating properly. When the (BITE) test fails, the controller 102 sets the lock out flag and prevents an associated ECB 130 to turn ON. In one scenario, the ECB 130 is locked OFF based on the lock out flag stored in non-volatile memory, and a fault indication is provided to a user, via the GUI of the remote device 142. In this manner, exposure time of dormant failed GFI is minimized.

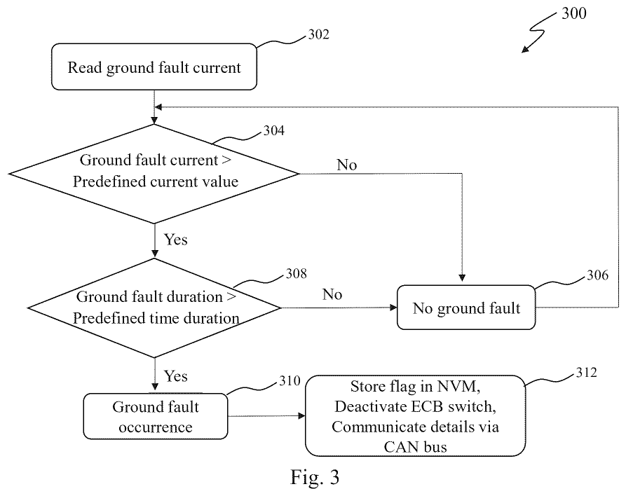

FIG. 3 illustrates a flowchart 300 of a method of ground fault detection by the GFI 100, in accordance with an embodiment of the present invention. In this regard, each block may represent a module, segment, or portion of code, which comprises one or more executable instructions for implementing the specified logical function(s). It should also be noted that in some alternative implementations, the functions noted in the blocks may occur out of the order noted in the drawings. For example, two blocks shown in succession in FIG. 3 may in fact be executed substantially concurrently or the blocks may sometimes be executed in the reverse order, depending upon the functionality involved. Any process descriptions or blocks in flow charts should be understood as representing modules, segments, or portions of code which include one or more executable instructions for implementing specific logical functions or steps in the process, and alternate implementations are included within the scope of the example embodiments in which functions may be executed out of order from that shown or discussed, including substantially concurrently or in reverse order, depending on the functionality involved. In addition, the process descriptions or blocks in flow charts should be understood as representing decisions made by a hardware structure such as a state machine.

The controller 102 reads value/magnitude of ground fault current, at step 302. The controller 102 compares the ground fault current with a predefined current value, at step 304. In case the ground fault current is identified to not exceed the predefined current value, it is determined that no ground fault has occurred, at step 306. Alternatively, at step 304, if the ground fault current is identified to exceed the predefined current value, a duration of the ground fault current is compared with a predefined time duration, at step 308. In case the duration of the ground fault current is identified to not exceed the predefined time duration, it is determined that no ground fault has occurred, at step 306. Alternatively, at step 308, if the duration of the ground fault current is identified to exceed the predefined time duration, it is determined that a ground fault has occurred, at step 310. Further, ECB switch 132 is deactivated, the lock out flag is stored in non-volatile memory, and the details of the ground fault are communicated to the GUI of a remote device 142 via the CAN bus 140, at step 312.

In an above described manner, ground fault can be detected by the GFI 100 in real time. Upon detecting a ground fault, the controller 102 sends a command to the ECB 130 via the discrete electrical signal 150, for turning OFF a respective switch, to disconnect the power supply line from the load 110. Also, a Built In Test (BITE) can be performed on the GFI 100 in a similar manner. For performing the BITE, the controller 102 sends a BITE enable signal to the driver circuit 104 for generating a test signal in the test winding 112 of the current transformer 106. The test signal in the test winding 112 results into generation of ground fault current in the secondary winding 114. Successful identification of the ground fault current indicates passing of the BITE. In case of failure of BITE, the controller 102 stores a lock out flag in a non-volatile memory. The lock out flag can be cleared remotely from a control panel or a GUI after a repair/maintenance task is completed.

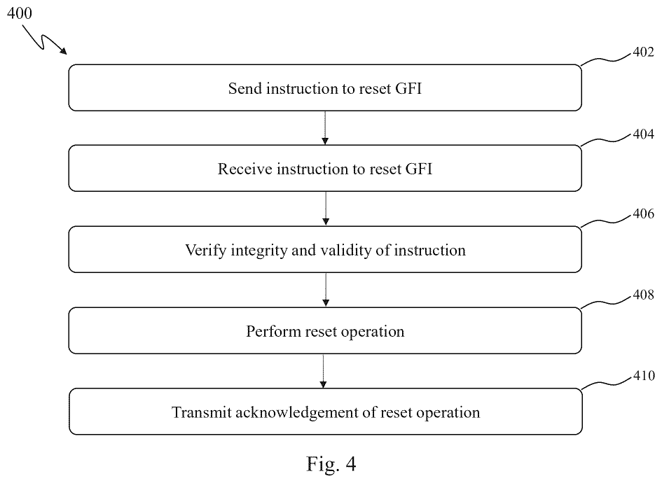

FIG. 4 illustrates a flowchart 400 of a method of resetting the GFI 100 after ground fault detection, in accordance with an embodiment of the present invention. In this regard, each block may represent a module, segment, or portion of code, which comprises one or more executable instructions for implementing the specified logical function(s). It should also be noted that in some alternative implementations, the functions noted in the blocks may occur out of the order noted in the drawings. For example, two blocks shown in succession in FIG. 4 may in fact be executed substantially concurrently or the blocks may sometimes be executed in the reverse order, depending upon the functionality involved. Any process descriptions or blocks in flow charts should be understood as representing modules, segments, or portions of code which include one or more executable instructions for implementing specific logical functions or steps in the process, and alternate implementations are included within the scope of the example embodiments in which functions may be executed out of order from that shown or discussed, including substantially concurrently or in reverse order, depending on the functionality involved. In addition, the process descriptions or blocks in flow charts should be understood as representing decisions made by a hardware structure such as a state machine.

At step 402, an instruction for resetting the GFI 100 is sent via the CAN bus 140 using a control panel or a GUI of a remote device. The instruction is transmitted, as a message containing specific data bytes representing the command, over the CAN bus 140.

At step 404, the instruction for resetting the GFI 100 is received. The controller 102 constantly listens to the CAN bus 140 for incoming messages. Upon receiving the instruction, the controller 102 identifies the message based on its unique identifier (ID) and extracts relevant data bytes representing a reset command.

At step 406, the controller 102 verifies integrity and validity of the instruction. This may involve checking message ID, data bytes, and a checksum or error-correction code to ensure that the instruction is genuine and intended for the GFI 100.

At step 408, after the instruction is validated, the controller 102 performs a reset operation by clearing the lock out flag in non-volatile memory. This removes the lock out condition on the discrete electrical signal 150 to the ECB microcontroller 134 for restoring the power supply to the load 110.

At step 410, upon successful reset of the GFI 100, the controller 102 transmits a status message or acknowledgment onto the CAN bus 140, for informing other devices on a network about completion of the reset operation.

After the reset operation is completed, the controller 102 continues to monitor the GFI 100 for any further abnormalities or faults. Such continuous monitoring ensures that the GFI 100 remains in a safe and operational state.

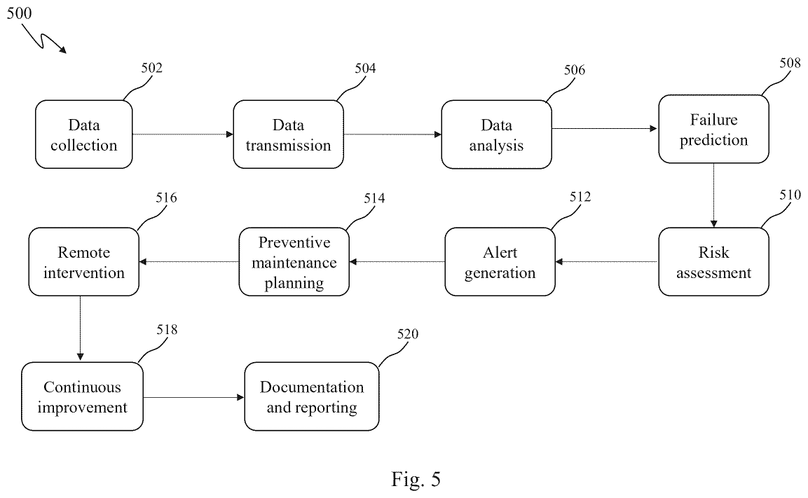

FIG. 5 illustrates a flowchart 500 of a method of performing predictive maintenance and diagnostics of a GFI using remote function, in accordance with an embodiment of the present invention. In this regard, each block may represent a module, segment, or portion of code, which comprises one or more executable instructions for implementing the specified logical function(s). It should also be noted that in some alternative implementations, the functions noted in the blocks may occur out of the order noted in the drawings. For example, two blocks shown in succession in FIG. 5 may in fact be executed substantially concurrently or the blocks may sometimes be executed in the reverse order, depending upon the functionality involved. Any process descriptions or blocks in flow charts should be understood as representing modules, segments, or portions of code which include one or more executable instructions for implementing specific logical functions or steps in the process, and alternate implementations are included within the scope of the example embodiments in which functions may be executed out of order from that shown or discussed, including substantially concurrently or in reverse order, depending on the functionality involved. In addition, the process descriptions or blocks in flow charts should be understood as representing decisions made by a hardware structure such as a state machine.

At step 502, data collection is performed by the controller 106. The controller 106 continuously monitors health of the GFI 100 by sensing the ground fault current, performing BITE test whenever the RCI circuit 118 is turned ON or on-demand during maintenance.

At step 504, data transmission is performed. The controller 106 transmits the data to a control panel or a GUI remotely via the CAN bus 140.

At step 506, data analysis is performed. Specifically, data analysis techniques are applied on the data for identifying patterns, trends, and anomalies.

At step 508, failure prediction is performed. By analysing historical data and current trends, potential failure of the GFI 100 is predicted. For predicting the potential failure, machine learning models that are previously trained to recognize patterns indicative of impending failures are used.

At step 510, risk assessment is done. Predicted failures are assessed based on severity and potential impact on operation of a system utilizing the GFI 100. Risk levels are assigned to prioritize maintenance actions.

At step 512, an alert is generated if the analysis detects a potential failure of the system. The alert may be sent to a maintenance personnel through a GUI or displayed on a control panel.

At step 514, preventive maintenance planning is done. Based on the predicted failures and associated risks, preventive maintenance plans are formulated. Further, maintenance schedules are adjusted to address potential issues before they escalate.

At step 516, remote intervention may take place. Maintenance teams may remotely access the system to perform diagnostic checks or pre-emptive maintenance tasks.

At step 518, feedback from predictive maintenance actions is used to refine and improve the predictive models. Continuous monitoring and analysis help in updating the prediction algorithms for better accuracy over time.

At step 520, documentation and reporting are done. Details of predicted failures, actions taken, and outcomes are documented. Reports may be generated to track effectiveness of predictive maintenance efforts.

By implementing remote diagnostics for predicting latent failures, organizations can proactively address potential issues, minimize downtime, and optimize maintenance resources. This approach shifts maintenance from a reactive to a proactive and predictive model, improving overall equipment reliability and operational efficiency.

The GFI described above provides the technical advancements mentioned subsequently. Because the two threshold values defining operation of the GFI i.e. the predefined current value (ground fault threshold current) and the predefined time period are configurable, the GFI can be configured for use in different applications. Specifically, a single GFI circuit could be programmed to handle ground faults in different applications, thereby eliminating the need of fabricating different GFI circuits for different applications. The predefined time period can be set for a particular application to prevent erroneous detection of transient current, momentary surge, or noise as ground faults. Latent failure of the GFI circuit can be tested remotely and the GFI circuit can be reset remotely, by transmitting instructions over a CAN bus.

Although implementations of a system for ground fault detection and avoidance has been described in language specific to structural features and/or methods, it is to be understood that the appended claims are not necessarily limited to the specific features or methods described. Rather, the specific features and methods are disclosed as examples of implementations of a system for interruption of electrical fault current.

We claim:

1. A Ground Fault Interrupter (GFI) (100) comprising:
a current transformer (106) for sensing ground fault current flowing through a power line (108) supplying electrical power to a load;
a controller (102) configured to:
receive details of the ground fault current from the current transformer (106);
determine that the ground fault current exceeds a predefined current value for a predefined time period; and
send a first instruction over a discrete electrical signal (150) to an Electronic Circuit Board (ECB) (130) to deactivate a switch (132) meant for transferring the electrical power from the line (108) to the load, for protecting the load (110) from the ground fault current; and
the first CAN transceiver (120) configured to receive a second instruction over a CAN bus (140) for resetting position of the switch (132), after the ground fault current is handled.

2. The GFI (100) as claimed in claim 1, further comprises a GFI driver (104) for generating a test signal in a test winding (112) of the current transformer (106), during remote testing of the GFI (100), wherein the test signal is generated based on a third instruction received from the controller (102) and results into generation of the ground fault current in the secondary winding (114).

3. The GFI (100) as claimed in claim 2, wherein the controller (102) sends the third instruction to the driver circuit (104) based on a user command provided using a Graphical User Interface (GUI) of a remote device connected with the CAN bus (140).

4. The GFI (100) as claimed in claim 2, wherein the GFI (100) eliminates dormant failure of a GFI sensing function.

5. The GFI (100) as claimed in claim 2, further comprises a non-volatile memory for storing a lock out flag when the ground fault current exceeds a predefined value and a predefined time has passed or a Built In Test (BITE) fails, during remote testing of the GFI (100).

6. The GFI (100) as claimed in claim 1, wherein the predefined current value and the predefined time period are configurable.

7. The GFI (100) as claimed in claim 1, wherein the switch (132) is a semiconductor switch selected from a group consisting of Metal-oxide-semiconductor Field-effect Transistor (MOSFET), thyristor, and Insulated-Gate Bipolar Transistor (IGBT).

8. The GFI (100) as claimed in claim 1, further comprises a signal conditioning circuit (116) for processing the ground fault current and providing a value of the ground fault current to the controller (102).
